(19) United States
(12) Patent Application Publication
(10) Pub. No.: US 2025/0160152 A1
(43) Pub. Date: May 15, 2025

(54) DISPLAY DEVICE AND ELECTRONIC DEVICE INCLUDING THE SAME

(71) Applicant: Samsung Display Co., Ltd., Yongin-Si (KR)

(72) Inventors: JINSUNG AN, Yongin-si (KR); SUNGHO KIM, Yongin-si (KR)

(21) Appl. No.: 18/935,744

(22) Filed: Nov. 4, 2024

(30) Foreign Application Priority Data
Nov. 15, 2023 (KR) 10-2023-0158481

(51) Int. Cl. H10K 59/131; H10K 59/121; H10K 59/126

(52) U.S. Cl. CPC H10K 59/131; H10K 59/1213; H10K 59/1216; H10K 59/126

(57) ABSTRACT

A display device includes a substrate, an active pattern including a first area, a second area, a first channel area, and a second channel area, a first conductive layer, a second conductive layer, a first electrode pattern including a first blocking pattern protruding from a portion overlapping the first area toward the second channel area, a second electrode pattern including a second blocking pattern protruding from a portion overlapping the first electrode pattern toward the first channel area and overlapping the first channel area, and a first initialization voltage line including a third blocking pattern overlapping the second channel area.

### CROSS-REFERENCE TO RELATED APPLICATION(S)

This application claims priority to Korean Patent Application No. 10-2023-0158481, filed on Nov. 15, 2023, which is hereby incorporated by reference for all purposes as if fully set forth herein.

### BACKGROUND

### 1. Field

Embodiments are related to a display device. More particularly, embodiments are related to a display device including an oxide semiconductor.

### 2. Description of the Related Art

A display device is a device that displays images to provide visual information to users. Recently, there is a growing demand for technology to reduce a power consumption of display devices. Accordingly, low-frequency driving methods for driving the display device at relatively low frequencies are being studied.

In the case of a low-frequency driving method, a leakage current may be generated due to a light from an outside. Accordingly, there is a problem in that the flicker phenomenon is recognized by the user.

### SUMMARY

Embodiments provide a display device with improved low-frequency characteristics.

A display device according to an embodiment may include a substrate, an active pattern disposed on the substrate and including a first area, a first channel area disposed adjacent to the first area in a first direction, a second area spaced apart from the first area in a second direction intersecting the first direction, and a second channel area disposed between the first area and the second area, a first conductive layer disposed on the active pattern and including a first gate voltage line overlapping the first channel area and a second gate voltage line overlapping the second channel area, a second conductive layer disposed on the first conductive layer and including a bias line overlapping the second area and a first stabilization electrode overlapping a portion of the first area, a first electrode pattern disposed on the second conductive layer and including a first blocking pattern protruding from a portion overlapping the first area toward the second channel area, a second electrode pattern disposed on the first electrode pattern and including a second blocking pattern protruding from a portion overlapping the first electrode pattern toward the first channel area and overlapping the first channel area, and a first initialization voltage line disposed on the first electrode pattern, including a third blocking pattern overlapping the second channel area and extending along the first direction.

In an embodiment, the first blocking pattern may overlap a portion of the first stabilization electrode.

In an embodiment, the first blocking pattern may adjoin the first stabilization electrode in a plan view.

In an embodiment, the third blocking pattern may overlap a portion of the first stabilization electrode.

In an embodiment, the active pattern may further include a third area disposed adjacent to the first channel area in the first direction, a third channel area disposed adjacent to the third area in a direction opposite to the second direction, and a fourth channel area disposed adjacent to the second area in a direction opposite to the first direction.

In an embodiment, the third blocking pattern may overlap at least a portion of the fourth channel area.

In an embodiment, a portion of the first gate voltage line may overlap the third channel area, and a portion of the second gate voltage line may overlap the fourth channel area.

In an embodiment, the first gate voltage line may include first gate electrodes overlapping the first channel area and the third channel area, respectively, and the first channel area, the third channel area, and the first gate electrodes may form a compensate transistor.

In an embodiment, the second gate voltage line may include second gate electrodes overlapping the second channel area and the fourth channel area, and the second channel area, the fourth channel area, and the second gate electrodes may form an initialization transistor.

In an embodiment, the first stabilization electrode may overlap the third area of the active pattern to form a first stabilization capacitor.

In an embodiment, the bias voltage line may overlap the second area of the active pattern to form a second stabilization capacitor.

In an embodiment, the display device may further include a second initialization voltage line disposed on a same layer as the first electrode pattern, overlapping each of a portion of the first channel area and a portion of the second blocking pattern, and extending along the second direction, and a power voltage line disposed on a same layer as the first initialization voltage line and formed integrally with the second electrode pattern.

In an embodiment, the display device may further include a light-emitting element layer disposed on the first initialization voltage line and the power voltage line and including a pixel electrode, a light-emitting layer disposed on the pixel electrode, and a common electrode disposed on the light-emitting layer and a pixel defining layer disposed on the pixel electrode and including a light-blocking material.

A display device according to an embodiment may include a light-emitting element, a driving transistor configured to supply a driving current to the light-emitting element, a compensate transistor including a first sub-transistor and a second sub-transistor, the first sub-transistor including an output terminal electrically connected to a gate electrode of the driving transistor, the second sub-transistor including an output terminal electrically connected to an input terminal of the first sub-transistor and an input terminal electrically connected to an output terminal of the driving transistor, an initialization transistor including a third sub-transistor and a fourth sub-transistor, the third sub-transistor including an output terminal electrically connected to the gate electrode of the driving transistor, the fourth sub-transistor including an output terminal electrically connected to an input terminal of the third sub-transistor and an input terminal electrically connected to an initialization voltage line, a first blocking pattern disposed on the gate electrode of the driving transistor and disposed between a portion of an active pattern intersecting with the output terminal of the first sub-transistor and the output terminal of the third sub-transistor and the third sub-transistor, a second blocking pattern disposed on the first blocking pattern and overlapping at least a portion of the first sub-transistor, and a third blocking pattern disposed on the first blocking pattern and overlapping the third sub-transistor and at least a portion of the fourth sub-transistor.

In an embodiment, the display device may further include a first electrode pattern electrically connecting the gate electrode of the driving transistor and each of the output terminal of the first sub-transistor and the output terminal of the third sub-transistor.

In an embodiment, the first blocking pattern may be formed integrally with the first electrode pattern.

In an embodiment, the second blocking pattern may be formed integrally with a second electrode pattern and a power voltage line, the second electrode pattern overlapping a portion of the first blocking pattern, the power voltage line extended from the second electrode pattern, and the third blocking pattern is formed integrally with the initialization voltage line disposed on a same layer as the power voltage line.

In an embodiment, the display device may further include a first stabilization capacitor disposed on each of the first sub-transistor and the second sub-transistor and located between the first sub-transistor and the second sub-transistor, and a second stabilization capacitor disposed on each of the third sub-transistor and the fourth sub-transistor and located between the third sub-transistor and the fourth sub-transistor.

In an embodiment, the first stabilization capacitor includes a first stabilization electrode overlapping a portion of the active pattern disposed between the input terminal of the first sub-transistor and the output terminal of the second sub-transistor, and the second stabilization capacitor includes a second stabilization electrode overlapping a portion of the active pattern disposed between the input terminal of the third sub-transistor and the output terminal of the fourth sub-transistor.

In an embodiment, each of the first blocking pattern and the third blocking pattern overlaps a portion of the first stabilization electrode.

In a display device according to embodiments of the present disclosure, the display device may include an active pattern including first to third areas, first to fourth sub-transistors, a first electrode pattern including a first blocking pattern, a second electrode pattern including a second electrode pattern, and an initialization voltage line including a third blocking pattern. The first blocking pattern may overlap a portion of the first area by protruding from a portion of the first electrode pattern overlapping the first area toward the third sub-transistor and the third blocking pattern may overlap the third sub-transistor. In addition, the second blocking pattern may overlap the first sub-transistor.

Accordingly, an external light from an outside incident on the first sub-transistor, a portion of the first area adjacent to the first sub-transistor, and third sub-transistor may be blocked. Accordingly, a leakage current and a flicker phenomenon generated by the outside light may decrease and low-frequency characteristics of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is an enlarged plan view of an area A in FIG. 1.

FIG. 3 is a circuit diagram of sub-pixel included in a pixel in FIG. 2.

FIGS. 4, 5, 6, 7, 8, 9, 10, 11, and 12 are layout views illustrating the display device in FIG. 1.

FIG. 13 is an enlarged plan view of an area B in FIG. 12.

FIGS. 14, 15, and 16 are layout views illustrating the display device in FIG. 13 excluding some components.

FIG. 17 is a cross-sectional view illustrating a cross-section taken along line I-I′ of FIG. 13.

FIG. 18 is a block diagram illustrating an electronic device according to an embodiment.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

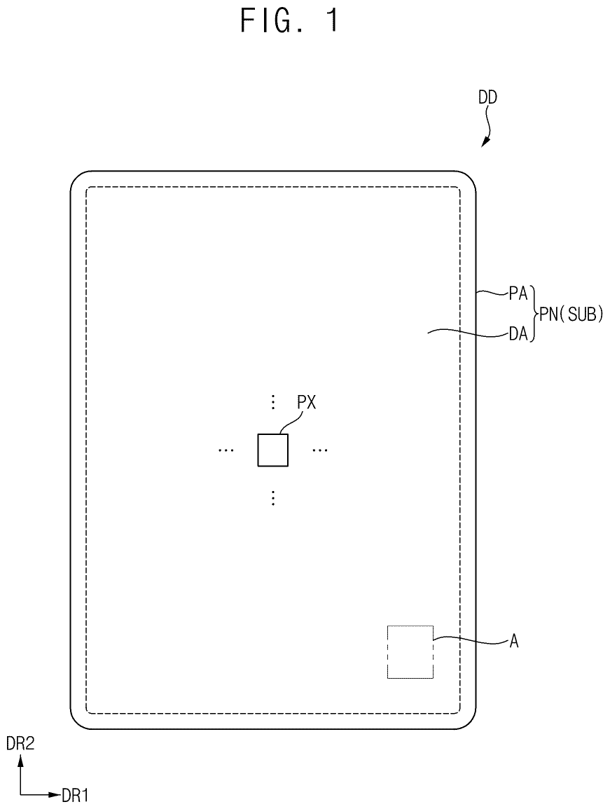

FIG. 1 is a plan view illustrating a display device according to an embodiment of the present disclosure.

Referring to FIG. 1, a display device DD according to an embodiment of the present disclosure may include a display panel PN. The display panel PN may include a display area DA and a peripheral area PA. The display panel PN may include a substrate SUB. Components for emitting a light may be disposed on the substrate SUB.

The display area DA may be an area that displays an image by generating a light or adjusting the transmittance of a light provided from an external light source. A plurality of pixels PX may be arranged in the display area DA. For example, each of the plurality of pixels PX may include a driving element and a light-emitting element.

The pixels PX may be arranged in a matrix form along a first direction DR1 and a second direction DR2 that intersects the first direction DR1. For example, the first direction DR1 and the second direction DR2 may be perpendicular to each other.

The peripheral area PA may be an area that does not display an image. In addition, the peripheral area PA may surround at least a portion of the display area DA. For example, the peripheral area PA may entirely surround the display area DA.

A driver for driving the display panel PN may be disposed in the peripheral area PA. For example, the driver may be configured to drive the pixels PX. The driver may include a data driver, a gate driver, a light emission driver, a power supply voltage generator, and a timing controller. The plurality of pixels PX may emit light based on signals received from the driver.

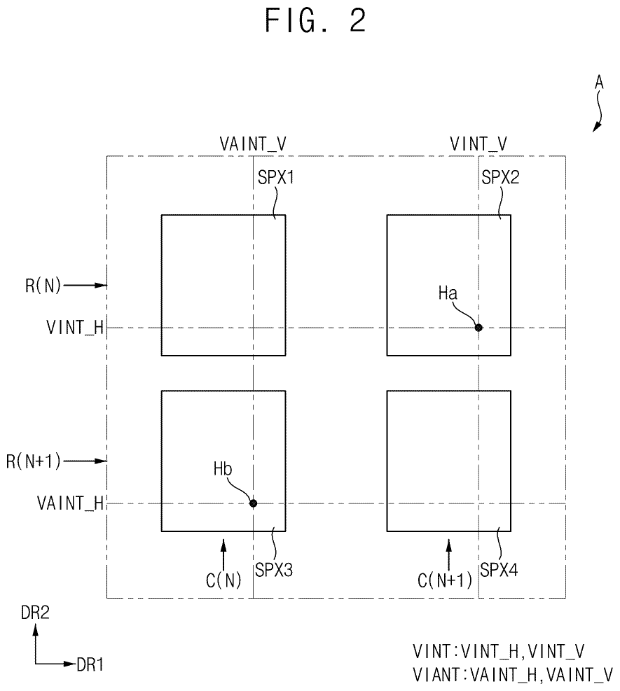

FIG. 2 is an enlarged plan view of an area A in FIG. 1. For example, FIG. 2 is a view for explaining a plurality of sub-pixels SPX1, SPX2, SPX3, and SPX4 included in each of the pixels PX in FIG. 1.

Referring to FIGS. 1 and 2, each of the plurality of pixels PX may include a first sub-pixel SPX1, a second sub-pixel SPX2, a third sub-pixel SPX3, and a fourth sub-pixel SPX4.

The first sub-pixel SPX1 and the third sub-pixel SPX3 may be arranged along the N-th column C(N). The second sub-pixel SPX3 and the fourth sub-pixel SPX4 may be arranged along the N+1-th column C(N+1). The N+1th column C(N+1) may be disposed adjacent to the Nth column C(N).

In addition, the first sub-pixel SPX1 and the second sub-pixel SPX2 may be arranged along the N-th row R(N). The third sub-pixel SPX2 and the fourth sub-pixel SPX4 may be arranged along the N+1-th row R(N+1). The N+1th row R(N+1) may be disposed adjacent to the Nth row R(N).

In this way, the arrangement of sub-pixels may be repeated up to preset rows and columns. For example, the first sub-pixel SPX1 and the third sub-pixel SPX3 may be arranged along odd-numbered columns, and the second sub-pixel SPX2 and fourth sub-pixel SPX4 may be arranged along even-numbered columns. In addition, the first sub-pixel SPX1 and the second sub-pixel SPX2 may be arranged along odd-numbered rows, and the third sub-pixel SPX3 and the fourth sub-pixel SPX4 may be arranged along even-numbered rows.

Each of the first sub-pixel SPX1, the second sub-pixel SPX, the third sub-pixel SPX3, and the fourth sub-pixel SPX4 may be connected to initialization voltage lines. The initialization voltage lines may include a first initialization voltage line VINT and a second initialization voltage line VAINT. Since the first initialization voltage line VINT and the second initialization voltage line VAINT are separated from each other, a color deviation may be improved at a low brightness.

The initialization voltage lines may have a mesh structure in a plan view. The first initialization voltage line VINT may include a horizontal portion VINT_H extending along the first direction DR1 and a vertical portion VINT_V extending along the second direction DR2. The second initialization voltage line VAINT may also include a horizontal portion VAINT_H extending along the first direction DR1 and a vertical portion VAINT_V extending along the second direction DR2.

The first initialization voltage line VINT_H and the second initialization voltage line VAINT_H extending parallel to the first direction DR1 may be alternately arranged along the second direction DR2. For example, each of the first sub-pixel SPX1 and the second sub-pixel SPX2 may be connected to the first initialization voltage line VINT. Each of the third sub-pixel SPX3 and the fourth sub-pixel SPX4 may be connected to the second initialization voltage line VAINT.

The initialization voltage lines may be electrically connected to the sub-pixels through a first hole Ha and a second hole Hb. For example, the first sub-pixel SPX1 located in the N-th row R(N) may overlap only the horizontal portion VINT_H of the first initialization voltage line VINT. The second initialization voltage line VAINT may be located in the N+1th row R(N+1). Accordingly, the first sub-pixel SPX1 may not overlap the horizontal portion VAINT_H of the second initialization voltage line VAINT. Meanwhile, the third sub-pixel SPX2 located in the N+1th row R(N+1) may overlap only the horizontal portion VAINT_H of the second initialization voltage line VAINT. Accordingly, the third sub-pixel SPX2 may not overlap the horizontal portion VINT_H of the first initialization voltage line VINT. However, as the first hole Ha and the second hole Hb are formed, the first sub-pixel SPX1 may receive a second initialization voltage through the second initialization voltage line VAINT through a connection line, and the third sub-pixel SPX2 may receive a first initialization voltage from the first initialization voltage line VINT.

The first to fourth sub-pixels SPX1, SPX2, SPX3, and SPX4 may have an RGBG pentile pixel arrangement. For example, the first sub-pixel SPX1 may emit a blue light, the third sub-pixel SPX3 may emit a red light, and each of the second sub-pixel SPX2 and fourth sub-pixel SPX4 may emit a green light. However, the present disclosure may not be limited to this, and may have various arrangements such as RBGB, RBRG pentile pixel arrangement, or RGB pixel arrangement.

In FIG. 2, each of the plurality of pixels PX is illustrated as having the initialization voltage lines, but the present disclosure may not be limited thereto. For example, the initialization voltage lines may be shared with pixels neighboring each of the plurality of pixels PX.

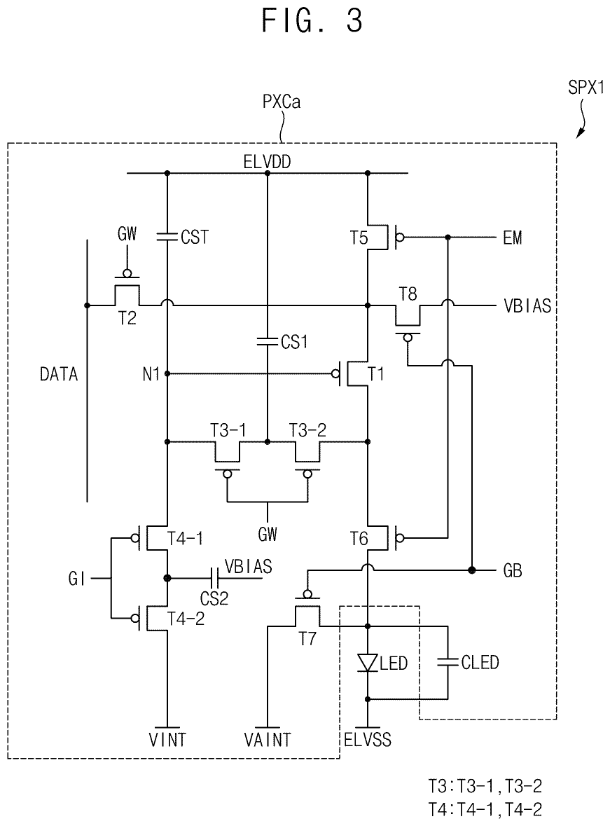

FIG. 3 is a circuit diagram of sub-pixel included in a sub-pixel in FIG. 2. For example, FIG. 3 is a circuit diagram of the first sub-pixel SPX1 in FIG. 2.

Referring to FIGS. 1, 2, and 3, the first sub-pixel SPX1 may include a light-emitting element LED and a pixel circuit PXCa. The pixel circuit PXCa may apply a driving current to the light-emitting element LED, and the light-emitting element LED may generate a light based on the driving current.

The pixel circuit PXCa may include at least one transistor and at least one capacitor. The pixel circuit PXCa may include a first transistor T1, a second transistor T2, a third transistor T3, a fourth transistor T4, a fifth transistor T5, a sixth transistor T6, and a seventh transistor T7, an eighth transistor T8, and a storage capacitor CST.

An input terminal of the first transistor T1 may be connected to a data voltage line DATA. For example, the first transistor T1 may receive a data voltage from the data voltage line DATA through the input terminal and generate the driving current corresponding to the data voltage.

An output terminal of the first transistor T1 may be connected to the light-emitting element LED. For example, the first transistor T1 may apply the driving current to the light-emitting element LED through the output terminal. A gate terminal of the first transistor T1 may be connected to a first node N1 which is connected to the storage capacitor CST. In this specification, the first transistor T1 may be referred to as a driving transistor.

An input terminal of the second transistor T2 may be connected to the data voltage line DATA. An output terminal of the second transistor T2 may be connected to the input terminal of the first transistor T1. A gate terminal of the second transistor T2 may be connected to a first gate voltage line GW.

Accordingly, the second transistor T2 may be turned on by the first gate voltage supplied from the first gate voltage line GW. During the period in which the second transistor T2 is turned on, the second transistor T2 may apply the data voltage to the input terminal of the first transistor T1.

The third transistor T3 may include a first sub-transistor T3-1 and a second sub-transistor T3-2 connected to each other. An input terminal of the first sub-transistor T3-1 may be connected to an output terminal of the second sub-transistor T3-2. An output terminal of the first sub-transistor T3-1 may be connected to the first node N1 which is connected to the gate terminal of the first transistor T1. An input terminal of the second sub-transistor T3-2 may be connected to the output terminal of the first transistor T1. The output terminal of the second sub-transistor T3-2 may be connected to the input terminal of the first sub-transistor T3-1. A gate terminal of the first sub-transistor T3-1 and a gate terminal of the second sub-transistor T3-2 may each be connected to the first gate voltage line GW.

Accordingly, the third transistor T3 may be turned on by the first gate voltage supplied from the first gate voltage line GW. During the period in which the third transistor T3 is turned on, the third transistor T3 may compensate for a threshold voltage of the first transistor T1 by diode-connecting the first transistor T1. In this specification, the third transistor T3 may be referred to as a compensation transistor.

The fourth transistor T4 may include a third sub-transistor T4-1 and a fourth sub-transistor T4-2 connected to each other. An input terminal of the third sub-transistor T4-1 may be connected to an output terminal of the fourth sub-transistor T4-2. The output terminal of the third sub-transistor T4-1 may be connected to the gate terminal of the first transistor T1. An input terminal of the fourth sub-transistor T4-2 may be connected to the first initialization voltage line VINT. The output terminal of the fourth sub-transistor T4-2 may be connected to the input terminal of the third sub-transistor T4-1. A gate terminal of the third sub-transistor T4-1 and a gate terminal of the fourth sub-transistor T4-2 may each be connected to a second gate voltage line GI.

Accordingly, the fourth transistor T4 may be turned on by the second gate voltage supplied from the second gate voltage line GI. During the period in which the fourth transistor T4 is turned on, the fourth transistor T4 may apply a first initialization voltage supplied from the first initialization voltage line VINT to the gate electrode of the first transistor T1. In this specification, the fourth transistor T4 may be referred to as an initialization transistor.

An input terminal of the fifth transistor T5 may be connected to a first power voltage line ELVDD. An output terminal of the fifth transistor T5 may be connected to the input terminal of the first transistor T1. A gate terminal of the fifth transistor T5 may be connected to an emission control line EM.

Accordingly, the fifth transistor T5 may be turned on by an emission control voltage supplied from the emission control line EM. During the period in which the fifth transistor T5 is turned on, the fifth transistor T5 may apply a first power voltage supplied from the first power voltage line ELVDD to the first transistor T1.

In an embodiment, the first power voltage supplied from the first power voltage line ELVDD and a second power voltage supplied from a second power voltage line ELVSS connected to the light-emitting element LED may each be a constant voltage. In this case, the first power voltage and the second power voltage may have different voltage levels.

An input terminal of the sixth transistor T6 may be connected to the output terminal of the first transistor T1. An output terminal of the sixth transistor T6 may be connected to the light-emitting element LED. A gate terminal of the sixth transistor T6 may be connected to the emission control line EM.

Accordingly, the sixth transistor T6 may be turned on by an emission control signal supplied from the emission control line EM. During the period in which the sixth transistor T6 is turned on, the sixth transistor T6 may apply the driving current to the light-emitting element LED.

An input terminal of the seventh transistor T7 may be connected to the second initialization voltage line VAINT. An output terminal of the seventh transistor T7 may be connected to an anode of the light-emitting element LED. A gate terminal of the seventh transistor T7 may be connected to a third gate voltage line GB.

Accordingly, the seventh transistor T7 may be turned on by a third gate voltage supplied from the third gate voltage line GB. During the period in which the seventh transistor T7 is turned on, the seventh transistor T7 may apply a second initialization voltage supplied from the second initialization voltage line VAINT to the light-emitting device LED.

An input terminal of the eighth transistor T8 may be connected to a bias voltage line VBIAS. An output terminal of the eighth transistor T8 may be connected to the input terminal of the first transistor T1. A gate terminal of the eighth transistor T8 may be connected to the third gate voltage line GB.

Accordingly, the eighth transistor T8 may be turned on by the third gate voltage supplied from the third gate voltage line GB. During the period in which the eighth transistor T8 is turned on, the eighth transistor T8 may apply a bias voltage to the first transistor T1.

The pixel circuit PXCa may include a storage capacitor CST, a first stabilization capacitor CS1, a second stabilization capacitor CS2, and a diode parasitic capacitor CLED.

A first terminal of the storage capacitor CST may be connected to the gate terminal of the first transistor T1. A second terminal of the storage capacitor CST may be connected to the first power voltage line ELVDD.

The storage capacitor CST may maintain a voltage level of the gate electrode of the first transistor T1 during the deactivation period of the first gate voltage supplied from the first gate voltage line GW.

A first terminal of the first stabilization capacitor CS1 may be connected to each of the input terminal of the first sub-transistor T3-1 and the output terminal of the second sub-transistor T3-2. A second terminal of the first stabilization capacitor CS1 may be connected to the first power voltage line ELVDD.

The first stabilization capacitor CS1 may maintain a voltage level at each of the input terminal of the first sub-transistor T3-1 and the output terminal of the second sub-transistor T3-2 relatively constant. Accordingly, a leakage current in the third transistor T3 may decrease, and low-frequency characteristics of the display device may be improved.

A first terminal of the second stabilization capacitor CS2 may be connected to each of the input terminal of the third sub-transistor T4-1 and the output terminal of the fourth sub-transistor T4-2. A second terminal of the second stabilization capacitor CS2 may be connected to the bias voltage line VBIAS.

The second stabilization capacitor CS2 may maintain a voltage level at each of the input terminal of the third sub-transistor T4-1 and the output terminal of the fourth sub-transistor T4-2 constant. Accordingly, a leakage current in the fourth transistor T4 may decrease, and low-frequency characteristics of the display device may be improved.

One end of the diode parasitic capacitor CLED may be connected to the anode electrode of the light-emitting element LED. The other end of the diode parasitic capacitor CLED may be connected to a cathode electrode of the light-emitting element LED.

However, the circuit structure of the pixel circuit PXCa of the present disclosure may not be limited to this illustrated in FIG. 3 and may have various structures. In addition, each of the second sub-pixel SPX2, the third sub-pixel SPX3, and the fourth sub-pixel SPX4 may have a pixel circuit structure that is substantially the same as a pixel circuit structure of the first sub-pixel SPX1.

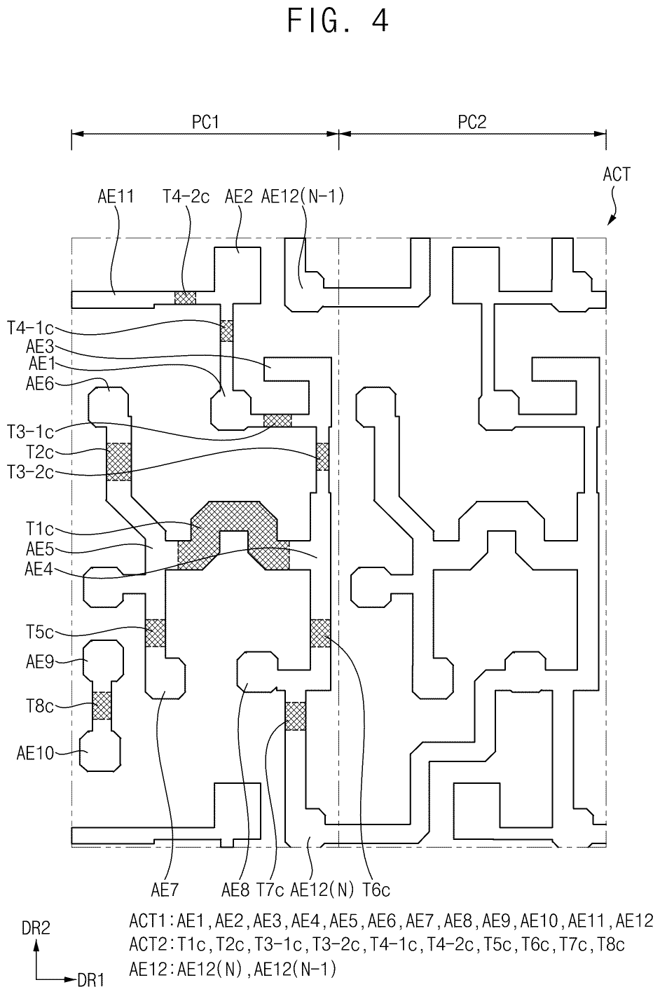

FIGS. 4, 5, 6, 7, 8, 9, 10, 11, and 12 are layout views illustrating the display device in FIG. 1.

The display device DD may include pixel circuits of the plurality of sub-pixels arranged adjacent to each other. The plurality of pixel circuits may include substantially the same components. For example, a first pixel circuit PC1 in FIGS. 4 to 12 may be a portion of the first sub-pixel (e.g., the first sub-pixel SPX1 in FIG. 2), and a second pixel circuit PC2 may be a portion of the second sub-pixel (e.g., the second sub-pixel SPX2 in FIG. 2).

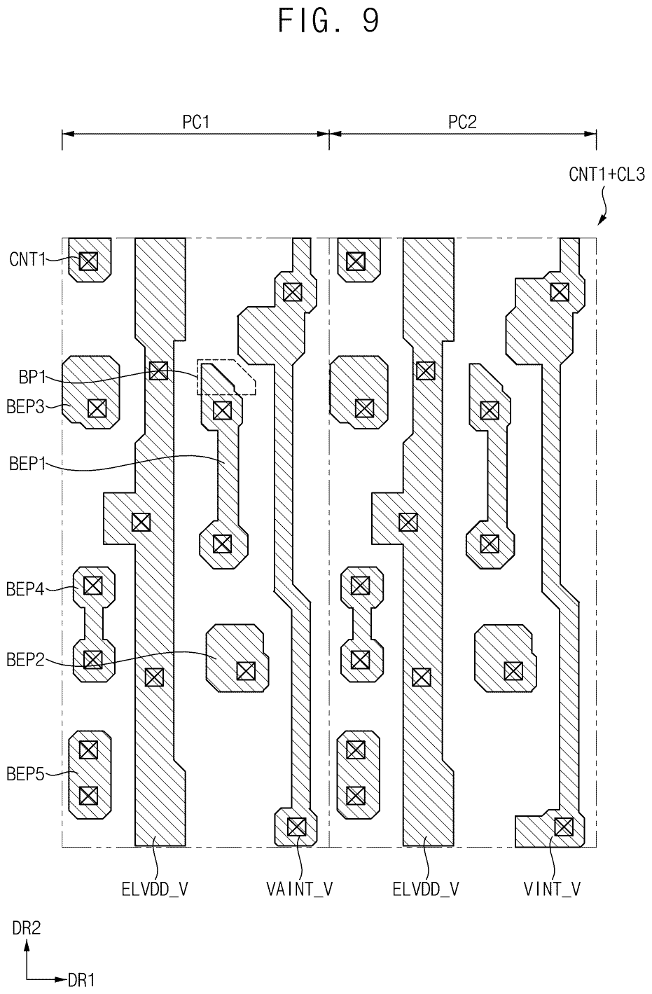

FIGS. 4, 5, 6, 7, 8, 9, 10, 11, and 12 are layout views to explain first to third blocking patterns (e.g., first to third blocking patterns BP1, BP2, and BP3 in FIGS. 9, 10, 11, and 12) covering the third transistor T3 and the fourth transistor T4. Hereinafter, for convenience of explanation, descriptions will focus on the first pixel circuit PC1 (e.g., the pixel circuit PXCa in FIG. 3).

FIG. 4 is a plan view for explaining the active pattern ACT.

Referring to FIGS. 1 and 4, the display device DD may include an active pattern ACT. The active pattern ACT may be disposed on the substrate SUB.

The active pattern ACT may include a first active area ACT1 and a second active area ACT2. The active pattern ACT may include the first active area ACT1 with relatively high conductivity and the second active area ACT2 with relatively low conductivity. For example, the first active area ACT1 may be a doped area doped with an n-type impurity or a p-type impurity. In addition, the second active area ACT2 may be a non-doped area or an area doped at a lower concentration than the first active area ACT1.

The first active area ACT1 may include first, second, third, fourth, fifth, sixth, seventh, eighth, ninth, tenth, eleventh, and twelfth areas AE1, AE2, AE3, AE4, AE5, AE6, AE7, AE8, AE9, AE10, AE11, and AE12. In this case, the twelfth area AE12 may include a nth area AE12(N) included in a nth pixel circuit in a nth row and (n−1)th area AE12(N−1) included in a (n−1)th pixel circuit in a (n−1)th row adjacent to the nth row. The first active area ACT1 may function as an electrode, a signal line, an input terminal of a transistor, an output terminal of a transistor, and/or a terminal of a capacitor.

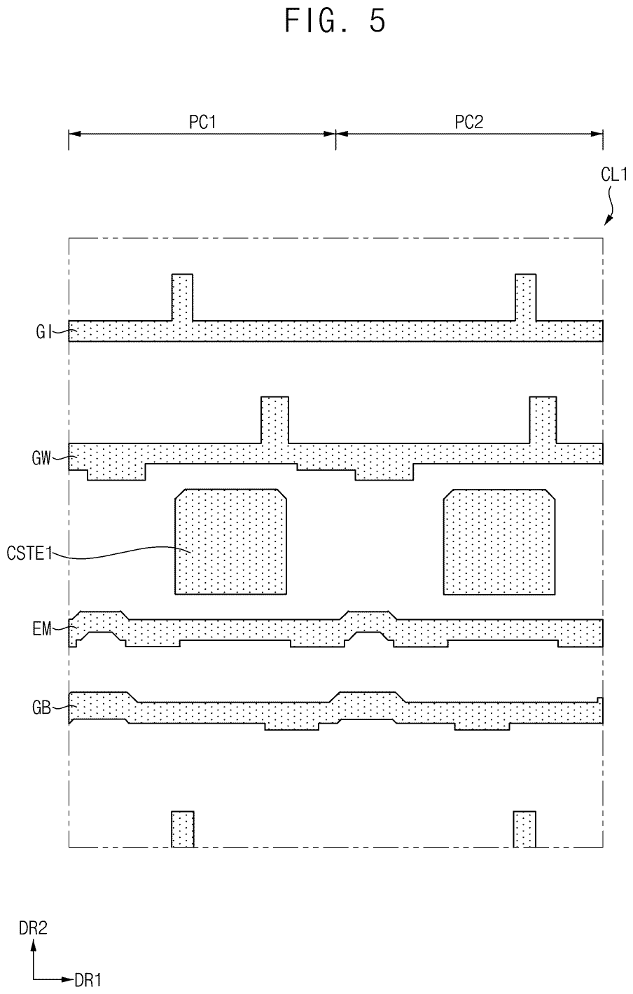

The second active area ACT2 may include a first channel area T3-1c, a second channel area T4-1c, a third channel area T3-2c, a fourth channel area T4-2c, and a fifth channel area T1c, a sixth channel area T2c, a seventh channel area T5c, an eighth channel area T6c, a ninth channel area T7c, and a tenth channel area T8c. The second active area ACT2 may be an area overlapping a first conductive layer (e.g., a first conductive layer CL1 in FIG. 5) and may be an area defining a channel area (or an active area) of the transistor.

The first area AE1 may be disposed adjacent to the first channel area T3-1c in a first direction DR1. The second area AE2 may be spaced apart from the first area AE1 in a second direction DR2 intersecting with the first direction DR1.

Referring further to FIG. 3, the output terminal of the first sub-transistor T3-1 may be defined in the first area AE1. The output terminal of the first sub-transistor T3-1 may be located in the first area AE1 to a direction opposite to the first direction DR1 from the first channel area T3-1c. The output terminal of the third sub-transistor T4-1 may be defined in the first area AE1. The output terminal of the third sub-transistor T4-1 may be located in the first area AE1 to a direction opposite to the second direction DR2 from the second channel area T4-1c. For example, a location of each of the output terminal of the first sub-transistor T3-1 and the output terminal of the third sub-transistor T4-1 may be disposed in the first area AE1.

Specifically, the output terminal of the first sub-transistor T3-1 and the output terminal of the third sub-transistor T4-1 may be a portion where the first area AE1 is electrically connected to a component (e.g., a first bottom electrode pattern BEP1 in FIG. 9) of a third conductive layer (e.g., a third conductive layer CL3 in FIG. 9) through a first contact hole (e.g., a first contact hole CNT1 in FIG. 9).

The second channel area T4-1c may located between the first area AE1 and the second area AE2. For example, the second channel area T4-1c may be disposed adjacent to the first area AE1 in the second direction DR2 and may be disposed adjacent to the second area AE2 in the direction opposite to the second direction DR2.

The input terminal of the third sub-transistor T4-1c and the output terminal of the fourth sub-transistor T4-2c may be defined in the second area AE2. The input terminal of the third sub-transistor T4-1c may be located in the second direction DR2 from the second channel area T4-1c. In addition, the output terminal of the fourth sub-transistor may be located in he first direction DR1 from the fourth channel area T4-2c. For example, a location of each of the input terminal of the third sub-transistor T4-1c and the output terminal of the fourth sub-transistor T4-2c may be disposed in the second area AE2.

The third area AE3 may be spaced apart from the first area AE1 in the first direction DR1. The third area AE3 may be disposed adjacent to the first channel area T3-1c in the first direction DR1. The third channel area T3-2c may be disposed adjacent to the third area AE3 in the direction opposite to the second direction DR2.

The input terminal of the first sub-transistor T3-1c and the output terminal of the second sub-transistor T3-2c may be defined in the third area AE3. The input terminal of the first sub-transistor T3-1c may be located in the first direction DR1 from the first channel area T3-1c. In addition, the output terminal of the second sub-transistor T3-2c may be located in the second direction DR2 from the third channel area T3-2c. For example, a location of each of the input terminal of the first sub-transistor T3-1c and the output terminal of the second sub-transistor T3-2c may be same in the third area AE3.

The fourth channel area T4-2c may be disposed adjacent to the second area AE2 in the direction opposite to the first direction DR1. The first area, second area, third area, the first channel area, the second channel area, the third channel area, and the fourth channel area AE1, AE2, AE3, T3-1c, T4-1c, T3-2c, and T4-2c may be areas in which blocking patterns blocking an external light incident into each of the third transistor T3 and the fourth transistor TR4 in FIG. 3 may be disposed.

The input terminal of the second sub-transistor T3-2c may be defined in the fourth area AE4. The input terminal of the second sub-transistor T3-2c may be located in the direction opposite to the second direction DR2 from the third channel area T3-2c.

The input terminal of the fourth sub-transistor T4-2c may be defined in the eleventh area AE11. The input terminal of the fourth sub-transistor T4-2c may be located in the direction opposite to the first direction DR1 from the fourth channel area T4-2c.

FIG. 5 is a plan view for explaining a first conductive layer CL1.

Referring to FIGS. 3 and 5, the pixel circuit PXCa may include the first conductive layer CL1. The first conductive layer CL1 may include the first gate voltage line GW, the second gate voltage line GI, a first storage electrode CSTE1, the emission control line EM, and the third gate voltage line GB. Each of the first gate voltage line GW, the second gate voltage line GI, the first storage electrode CSTE1, the emission control line EM, and the third gate voltage line GB may be disposed in a same layer.

The first gate voltage may be applied to the first gate voltage line GW. The second gate voltage may be applied to the second gate voltage line GI. The third gate voltage may be applied to the third gate voltage line GB. The emission control voltage may be applied to the emission control line EM.

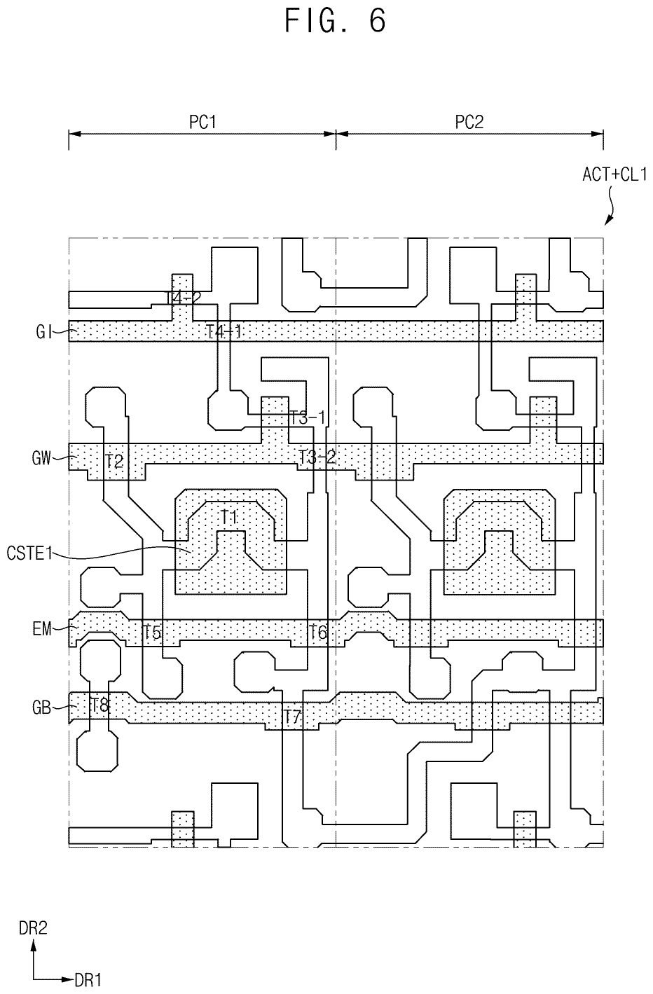

FIG. 6 is a plan view for explaining the active pattern ACT and the first conductive layer CL1.

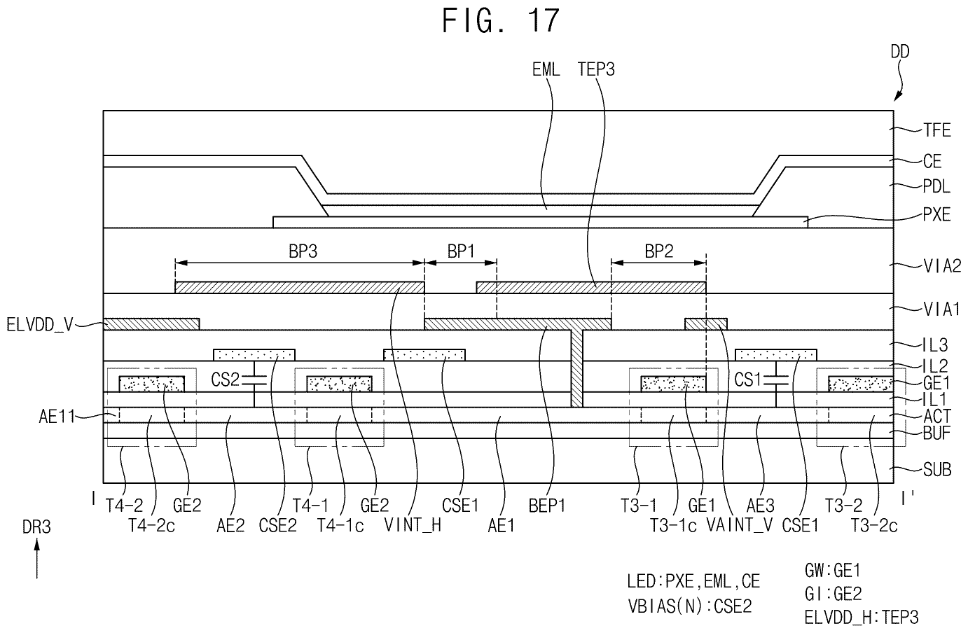

Referring to FIGS. 3, 4, 5, and 6, the first conductive layer CL1 may be disposed on the active pattern ACT. Specifically, a first insulating layer (e.g., a first insulating layer IL1 in FIG. 17) may be disposed on the active pattern ACT, and the first conductive layer CL1 may be disposed on the first insulating layer.

The first conductive layer CL1 may overlap the active pattern ACT. A portion of the first conductive layer CL1 overlapping the active pattern ACT may be defined as a gate electrode of a transistor.

Specifically, a portion of the first gate voltage line GW may overlap each of the first channel area T3-1c, the third channel area T3-2c, and the sixth channel area T2c. A portion of the first gate voltage line GW overlapping the first channel area T3-1c, the third channel area T3-2c, and the sixth channel area T2c may be the gate electrode of the first sub-transistor T3-1, the gate electrode of the second sub-transistor T3-2, and the gate electrode of the second transistor respectively.

A portion of the second gate voltage line GI may overlap each of the second channel area T4-1c and the fourth channel area T4-2c. A portion of the second gate voltage line GI overlapping the second channel area T4-1c and the fourth channel area T4-2c may be the gate electrode of the third sub-transistor and the gate electrode of the fourth sub-transistor respectively.

A portion of the first storage electrode CSTE1 may overlap the fifth channel area T1c. A portion of the first storage electrode CSTE1 overlapping the fifth channel area T1c may be referred to the gate electrode of the first transistor T1. That is, a portion of the first storage electrode CSTE1 overlapping the fifth channel area T1c may be the gate electrode of the driving transistor.

The emission control line EM may overlap each of the seventh channel area T5c and the eighth channel area T6c. A portion of the emission control line EM overlapping the seventh channel area T5c and the eighth channel area T6c may be the gate electrode of the fifth transistor T5 and the gate electrode of the sixth transistor T6 respectively.

The third gate voltage line GB may overlap each of the ninth channel area T7c and the tenth channel area T8c. A portion of the third gate voltage line GB overlapping the ninth channel area T7c and the tenth channel area T8c may be the gate electrode of the seventh transistor T7 and the gate electrode of the eighth transistor T8.

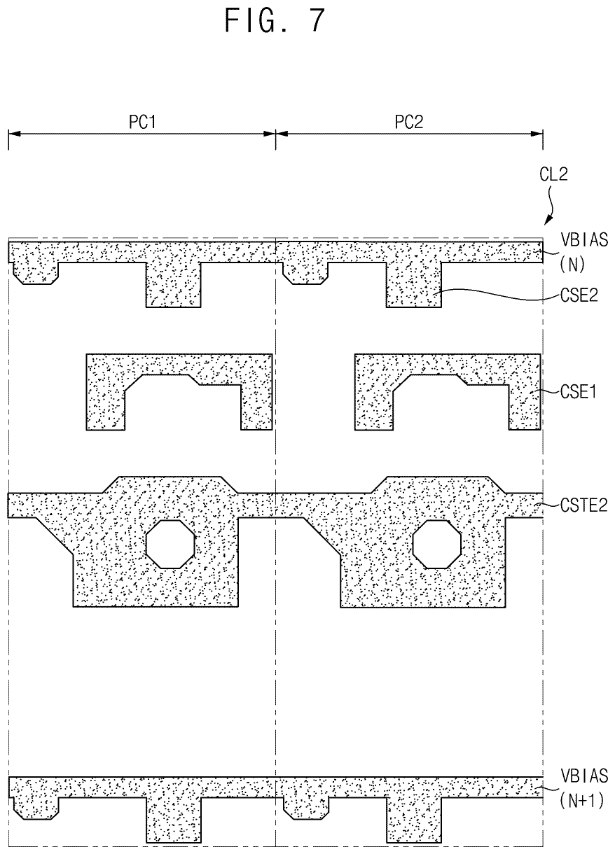

FIG. 7 is a plan view for explaining a second conductive layer CL2.

The second conductive layer CL2 may include a first stabilization capacitor CSE1, a bias voltage line VBIAS, and a second storage electrode CSTE2. The bias voltage may be applied to the bias voltage line VBIAS. The bias voltage line VBIAS may include a nth bias voltage line VBIAS(N) included in a pixel circuit in a nth row and (n+1)th bias voltage line VBIAS(N+1) included in a pixel circuit in a (n+1)th row.

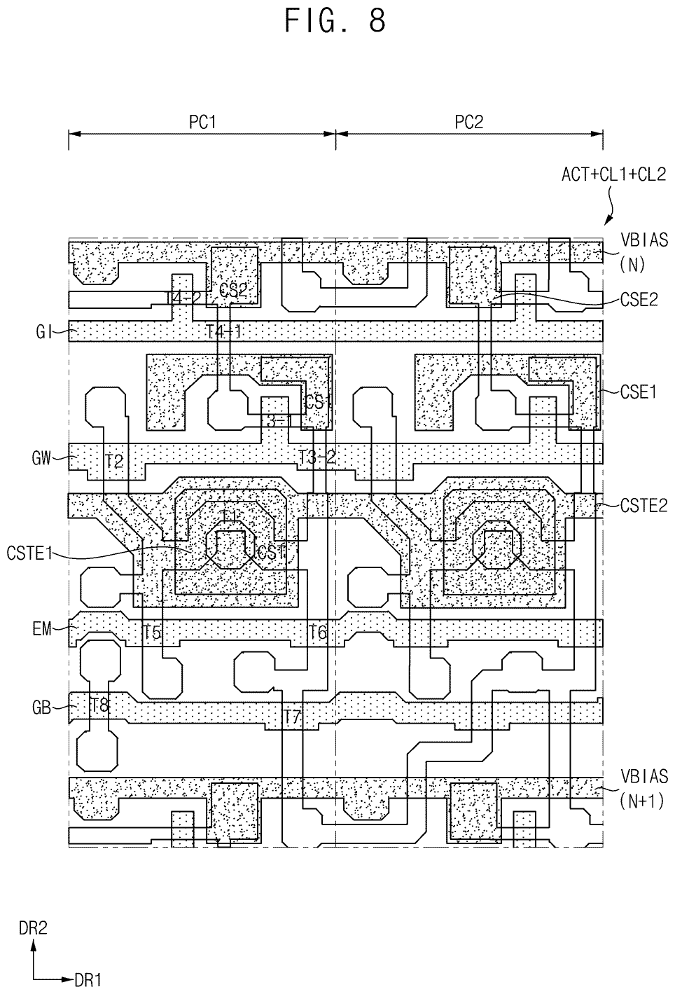

FIG. 8 is a plan view for explaining the active pattern ACT, the first conductive layer CL1, and the second conductive layer CL2.

Referring to FIGS. 4, 5, 6, 7, and 8, the second conductive layer CL2 may be disposed on the first conductive layer CL1. Specifically, a second insulating layer (e.g., a second insulating layer IL2 in FIG. 17) may be disposed on the first conductive layer, CL1 and the second conductive layer CL2 may be disposed on the second insulating layer.

The first stabilization electrode CSE1 may overlap the third area AE3 of the active pattern ACT. Specifically, the first stabilization electrode CSE1 may overlap the third area AE3 of the active pattern ACT defining the input terminal of the first sub-transistor T3-1 and the output terminal of the second sub-transistor T3-2. Accordingly, the first stabilization electrode CSE1 may constitute the first terminal of the first stabilization capacitor CS1.

The second storage electrode CSTE2 may overlap the first storage electrode CSTE1 to form the storage capacitor CST. In this case, the first storage electrode CSTE1 may form the first terminal of the storage capacitor CST. In addition, the second storage electrode CSTE2 may constitute the second terminal of the storage capacitor CST. An opening exposing a portion of the first storage electrode CSTE1 may be defined through the second storage electrode CSTE2.

The Nth bias voltage line VBIAS(N) may overlap the second area AE2 of the active pattern ACT. Specifically, the Nth bias voltage line VBIAS(N) may overlap the second area AE2 of the active pattern ACT defining the input terminal of the third sub-transistor T4-1 and the output terminal of the fourth sub-transistor T4-2. Accordingly, the first terminal of the second stabilization capacitor CS2 may be defined in the second stabilization electrode CSE2.

The N+1th bias voltage line VBIAS(N) may be substantially a same as the Nth bias voltage line VBIAS(N) except for the pixel circuit in the N+1th row.

FIG. 9 is a plan view for explaining the first contact hole CNT1 and the third conductive layer CL3.

Referring to FIG. 9, the third conductive layer CL3 may include the vertical portion VINT_V of the first initialization voltage line (e.g., the first initialization voltage line VINT), a first vertical power voltage line ELVDD_V, the second vertical portion VAINT_V of the second initialization voltage line (e.g., the second initialization voltage line VAINT), the first bottom electrode pattern BEP1, a second bottom electrode pattern BEP2, a third bottom electrode pattern BEP3, a fourth bottom electrode pattern BEP4, and a fifth bottom electrode pattern BEP5. The first bottom electrode pattern BEP1 may include the first blocking pattern BP1.

The first initialization voltage may be applied to the vertical portion VINT_V of the first initialization voltage line. The first power voltage may applied to the first vertical power voltage line ELVDD_V. The second initialization voltage may be applied to the vertical portion VAINT_V of the second initialization voltage line.

Each of the first, second, third, fourth, and fifth bottom electrode pattern BEP1, BEP2, BEP3, BEP4, and BEP5 may be spaced apart from each other. Each of the first, second, third, fourth, and fifth bottom electrode pattern BEP1, BEP2, BEP3, BEP4, and BEP5 may be spaced apart from signal lines (e.g., the vertical portion VINT_V of the first initialization voltage line, the first vertical power voltage line ELVDD_V, and the vertical portion VAINT_V of the second initialization voltage line) extending along the second direction DR2

Referring further to FIGS. 8 and 9, the first contact hole CNT1 may be a via hole to contact the third conductive layer CL3 to components (e.g., the active pattern ACT, or the first conductive layer CL1, or the second conductive layer CL2) disposed under the third conductive layer CL3. The third conductive layer CL3 may protrude toward he components disposed under the third conductive layer CL3 through the first contact hole CNT1.

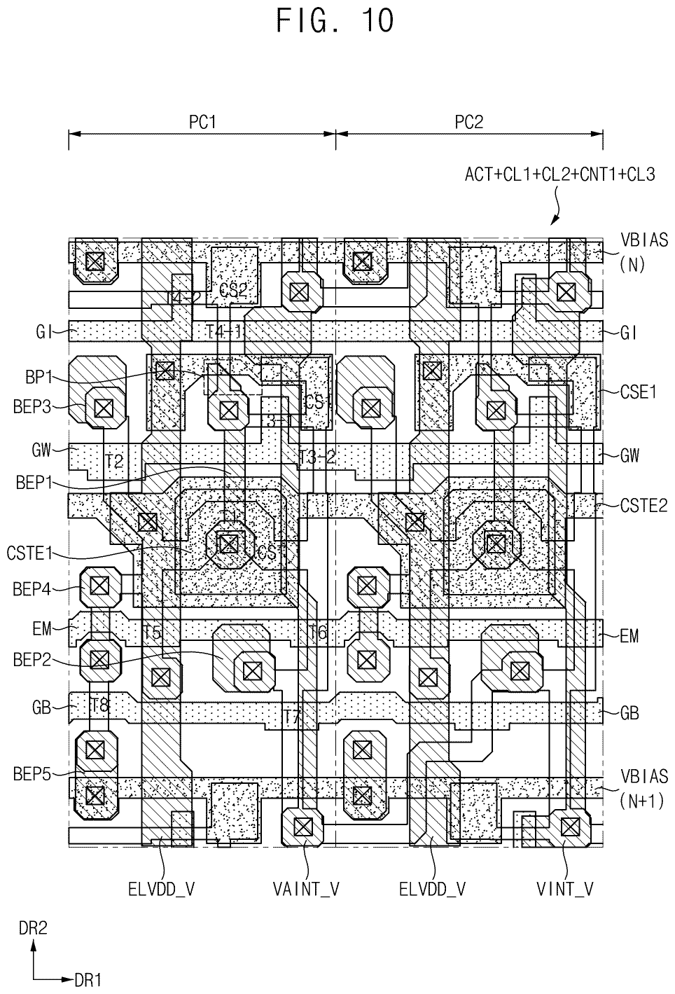

FIG. 10 is a plan view for explaining the first conductive layer CL1, the second conductive layer CL2, first contact hole CNT1, and the third conductive layer CL3. Specifically, a third insulating layer (e.g. a third insulating layer IL3) may be disposed on the second conductive layer CL2, the third conductive layer CL3 may be disposed on the third insulating layer. In addition, the first contact hole CNT1 which is formed through at least one among the first to third insulating layers in a thickness direction and exposes upper surfaces of the components disposed under the third conductive layer CL3b may be defined.

Referring to FIGS. 3, 4, and 10, the vertical portion VINT_V of the first initialization voltage line may contact the active pattern ACT. For example, the vertical portion VINT_V of the first initialization voltage line may be electrically connected to a portion of the second pixel circuit PC2 through the first contact hole CNT1. Accordingly, the vertical portion VINT_V of the first initialization voltage line may apply the first initialization voltage to the input terminal of the fourth sub-transistor T4-2.

The first vertical power voltage line ELVDD_V may contact the second storage electrode CSTE2. For example, the first vertical power voltage line ELVDD_V may be electrically connected to the second storage electrode CSTE2 through the first contact hole CNT. Accordingly, the first vertical power voltage line ELVDD_V may apply the first power voltage to the second storage electrode CSTE2.

The first vertical power voltage line ELVDD_V may contact the first stabilization electrode CSE1. For example, the first vertical power voltage line ELVDD_V may be electrically connected to the first stabilization electrode CSE1 through the first contact hole CNT1. Accordingly, the first vertical power voltage line ELVDD_V may supply the first power voltage to the first stabilization electrode CSE1.

The first vertical power voltage line ELVDD_V may contact the seventh area AE7 of the active pattern ACT. For example, the first vertical power voltage line ELVDD_V may be electrically connected to the seventh area AE7 of the active pattern ACT through the first contact hole CNT1. Accordingly, the first vertical power voltage line ELVDD_V may supply the first power voltage to the input terminal of the fifth transistor T5.

The vertical portion VAINT_V of the second initialization voltage line may contact the Nth area AE12(N) of the active pattern ACT. Accordingly, the vertical portion VAINT_V of the second initialization voltage line may provide the second initialization voltage to the input terminal of the seventh transistor T7.

The first bottom electrode pattern BEP1 may contact the first storage electrode CSTE1 and the first area AE1 of the active pattern ACT. For example, the first bottom electrode pattern BEP1 may be electrically connected to the first storage electrode CSTE1 and the first area AE1 of the active pattern ACT through the first contact holes CNT1. Specifically, the first bottom electrode pattern BEP1 may connect the first storage electrode CSTE1, which is the gate electrode of the first transistor T1, and the first area AE1 where the output terminal of the first sub-transistor T3-1 and the output terminal of the third sub-transistor T4-1 are disposed. Accordingly, the gate electrode of the first transistor T1, the output terminal of the first sub-transistor T3-1, and the output terminal of the third sub-transistor T4-1 may be electrically connected to each other in the first area AE1.

The first bottom electrode pattern BEP1 may include the first blocking pattern BP1 overlapping a portion of the first stabilization electrode CSE1. The first blocking pattern BP1 may be a portion of the first bottom electrode pattern BEP1 protruding in the second direction DR2 from a portion where the first bottom electrode pattern BEP1 overlaps the first area AE1. Accordingly, an external light incident into a portion of the first area AE1 may be blocked, a leakage current and a flicker phenomenon occurring due to the external light may decrease, and low-frequency characteristics of the display device may be improved.

Specifically, the first blocking pattern BP1 may block the external light, incident on the first area AE1 disposed adjacent to the third sub-transistor T4-1 in the direction opposite to the second direction DR2 with the first stabilization electrode CSE1 disposed between the first bottom electrode pattern BEP1 and the first area AE1. In this specification, the first bottom electrode pattern BEP1 may be referred to a first electrode pattern.

The second bottom electrode pattern BEP2 may contact the eighth area AE8 of the active pattern ACT. Specifically, the second bottom electrode pattern BEP2 may be electrically connected to the eighth area AE8, where the output terminal of the sixth transistor T6 and the output terminal of the seventh transistor T7 are disposed, through the first contact hole CNT1.

The third bottom electrode pattern BEP3 may contact the sixth area AE6 of the active pattern ACT. Specifically, the third bottom electrode pattern BEP3 may contact the sixth area AE6, which is the input terminal of the second transistor T2, through the first contact hole CNT1. The third bottom electrode pattern BEP3 may be connected to the data voltage line DATA. Accordingly, the data voltage applied to the data voltage line DATA may be transmitted to the input terminal of the second transistor T2 through the third bottom electrode pattern BEP3.

The fourth bottom electrode pattern BEP4 may contact each of the fifth and ninth areas AE5 and AE9 of the active pattern ACT. For example, the fourth bottom electrode pattern BEP4 may electrically connect the fifth area AE5 and the ninth area AE9 to each other. Specifically, the fourth bottom electrode pattern BEP4 may electrically connect the input terminal of the first transistor T1 and the output terminal of the eighth transistor T8. Accordingly, as described above, the bias voltage applied to the eighth transistor T8 may be transmitted to the first transistor T1.

The fifth bottom electrode pattern BEP5 may contact each of the N+1 bias voltage line VBIAS(N+1) and the tenth area AE10 of the active pattern ACT. Specifically, the fifth bottom electrode pattern BEP5 may electrically connect the N+1 bias voltage line VBIAS(N+1) and the input terminal of the eighth transistor T8 to each other through the first contact holes CNT1.

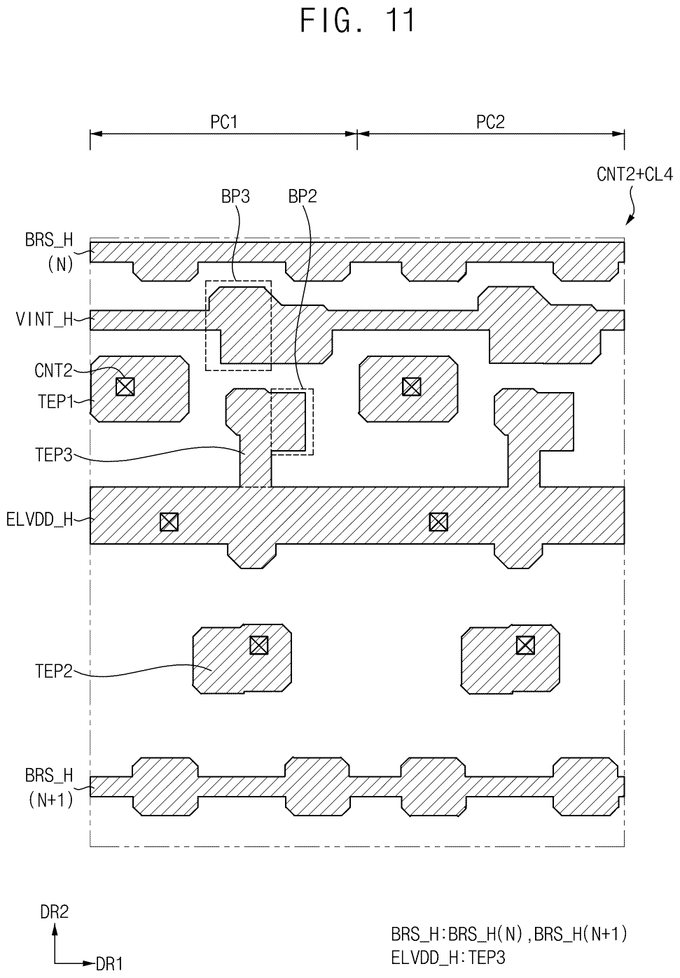

FIG. 11 is a plan view for explaining the second contact hole CNT2 and the fourth conductive layer CL4.

Referring to FIGS. 10 and 11, the horizontal bridge line BRS_H, a first horizontal power voltage line ELVDD_H, the horizontal portion VINT_H of the first initialization voltage line, a first top electrode pattern TEP1, and a second top electrode pattern TEP2 may be disposed on the third conductive layer with an insulating layer disposed therebetween.

The horizontal bridge line BRS_H may include a nth horizontal bridge line BRS_H(N) included in the pixel circuit in the nth row and a (n+1)th horizontal bridge line BRS_H(N+1) included in the pixel circuit in the (n+1)th row.

The first power voltage may be applied to the first horizontal power voltage line ELVDD_H. The first horizontal power voltage line ELVDD_H may include a third top electrode pattern TEP3. For example, the first horizontal power voltage line ELVDD_H and the third top electrode pattern TEP3 may form integrally. Specifically, the third top electrode pattern TEP3 may be a protruding portion of the first horizontal power voltage line ELVDD_H which protrudes from a portion of the first horizontal power voltage line ELVDD_H.

The first initialization voltage may be applied to the horizontal portion VINT_H of the first initialization voltage line. The horizontal portion VINT_H of the first initialization voltage line may include a third blocking pattern BP3.

Each of the first and second top electrode patterns TEP1 and TEP2 may be spaced apart from each other. Each of the first and second top electrode patterns TEP1 and TEP2 may be spaced apart from the signal lines (e.g., the horizontal bridge line BRS_H, a first horizontal power voltage line ELVDD_H, and the horizontal portion VINT_H of the first initialization voltage line) extending along the first direction DR1.

The second contact hole CNT2 may be a via hole to contact the fourth conductive layer CL4 and components (e.g. the third conductive layer CL3) disposed under the fourth conductive layer CL4. The fourth conductive layer CL4 may be connected to the components disposed under the fourth conductive layer CL4 through the second contact hole CNT2.

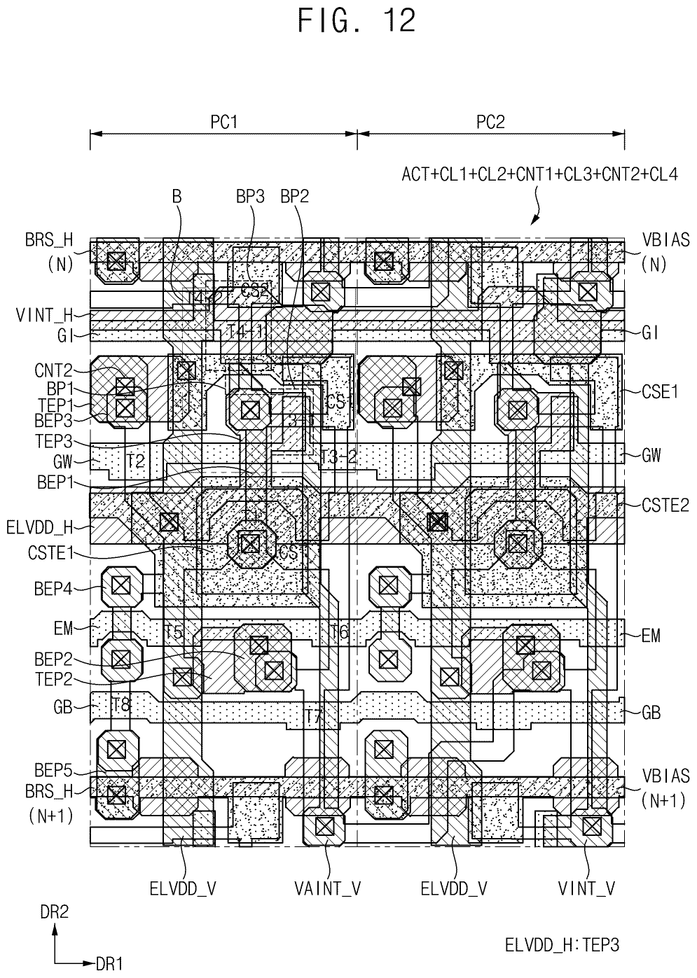

FIG. 12 is a plan view for explaining the first conductive layer CL1, the second conductive layer CL2, the first contact hole CNT1, the third conductive layer CL3, the second contact hole CNT2, and the fourth conductive layer CL4. Specifically, a first via insulating layer (e.g., a first via insulating layer VIA1 of FIG. 17) may be disposed on the third conductive layer CL3, and the fourth conductive layer CL4 may be disposed on the first via insulating layer VIAL. In addition, the second contact holes CNT2 which are formed through the first via insulating layer in a thickness direction and exposes an upper surface of the third conductive layer CL3 may be defined.

Referring to FIGS. 3 and 12, the first horizontal power voltage line ELVDD_H may be electrically connected to the first vertical power voltage line ELVDD_V through the second contact hole CNT2. The first horizontal power voltage line ELVDD_H may be electrically connected to the second storage electrode CSTE2, the first stabilization electrode CSE1, and the seventh area AE7 of the active pattern ACT.

The third top electrode pattern TEP3, which is a portion of the first horizontal power voltage line ELVDD_H, may include the second blocking pattern BP2 overlapping the first sub-transistor T3-1. The second blocking pattern BP2 may protrude from the third top electrode pattern TEP3 toward the first sub-transistor T3-1. Specifically, the second blocking pattern BP2 may protrude in the first direction DR1 from a portion of the third top electrode pattern TEP3 where the third top electrode pattern TEP3 overlaps the first lower electrode pattern BEP1. Accordingly, the external light incident on the first sub-transistor T3-1 may be blocked, a leakage current and a flicker phenomenon caused by the external light may decrease and low-frequency characteristics of the display device may be improved. In this specification, the third top electrode pattern TEP3 may be referred to as a second electrode pattern.

The second blocking pattern BP2 may overlap a portion of the vertical portion VAINT_V of the second initialization voltage line disposed adjacent to the first sub-transistor T3-1. In addition, the second blocking pattern BP2 may overlap a portion of the first gate voltage line GW disposed adjacent to the first sub-transistor T3-1. Accordingly, the second blocking pattern BP2 may cover the first sub-transistor T3-1 so that an upper surface of the active pattern ACT around the first sub-transistor T3-1 may not be exposed.

The horizontal portion VINT_H of the first initialization voltage line may be electrically connected to the vertical portion VINT_V of the first initialization voltage line through the second contact hole CNT2. The second contact hole connecting the horizontal portion VINT_H of the first initialization voltage line and the vertical portion VINT_V of the first initialization voltage line may be the first hole (e.g., the first hole Ha in FIG. 2) describe above.

The horizontal portion VINT_H of the first initialization voltage line may include the third blocking pattern BP3 overlapping the third sub-transistor T4-1. The third blocking pattern BP3 may overlap the third sub-transistor T4-1. Specifically, the third blocking pattern BP3 may protrude in the direction opposite to the first direction DR1 from a portion of the horizontal portion VINT_H where the horizontal portion VINT_H of the first initialization voltage line overlaps the vertical portion VAINT_V of the second initialization voltage line. Accordingly, the external light incident on the third sub-transistor T4-1 may be blocked, a leakage current and a flicker phenomenon caused by the external light may decrease, and low-frequency characteristics of the display device may be improved.

The third blocking pattern BP3 may overlap a portion of the first vertical power voltage line ELVDD_V and a portion of the fourth sub-transistor T4-2. In addition, the third blocking pattern may overlap a portion of the first stabilization electrode CSE1. Accordingly, the third blocking pattern BP3 may block the third sub-transistor T4-1 and a portion of the first area AE1 disposed adjacent to the third sub-transistor T4-1 with the first blocking pattern BP1 and the first stabilization electrode CSE1.

The first top electrode pattern TEP1 may overlap the third bottom electrode pattern BEP3. The first top electrode pattern TEP1 may contact the third bottom electrode pattern BEP3 through the second contact hole CNT2. The first top electrode pattern TEP1 may be disposed on the fourth conductive layer CL4, and connected to the data voltage line DATA extending along the second direction DR2. Accordingly, the data voltage applied from the data voltage line DATA may be supplied to the input terminal of the second transistor T2 through the first top electrode pattern TEP1 and the third bottom electrode pattern BEP3.

The second top electrode pattern TEP2 may overlap the second bottom electrode pattern BEP2. The second top electrode pattern TEP2 may contact the second bottom electrode pattern BEP2. The second top electrode pattern TEP2 may contact a pixel electrode (e.g., a pixel electrode PXE in FIG. 17) of the light-emitting element LED. Accordingly, the pixel electrode of the light-emitting element LED may be connected to the eighth area AE8 of the active pattern ACT through the second top electrode pattern TEP2 and the second bottom electrode pattern BEP2.

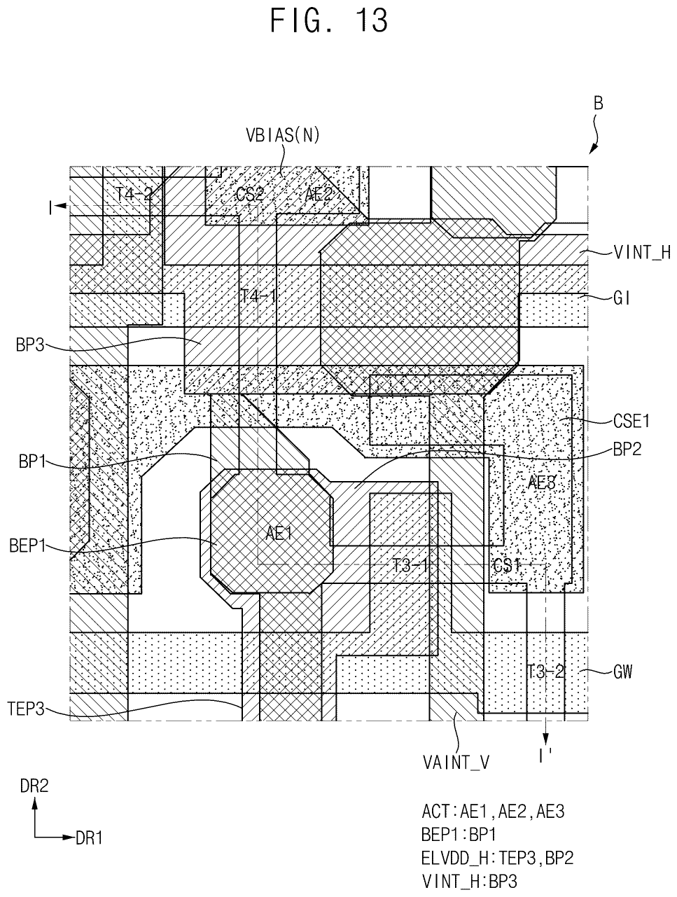

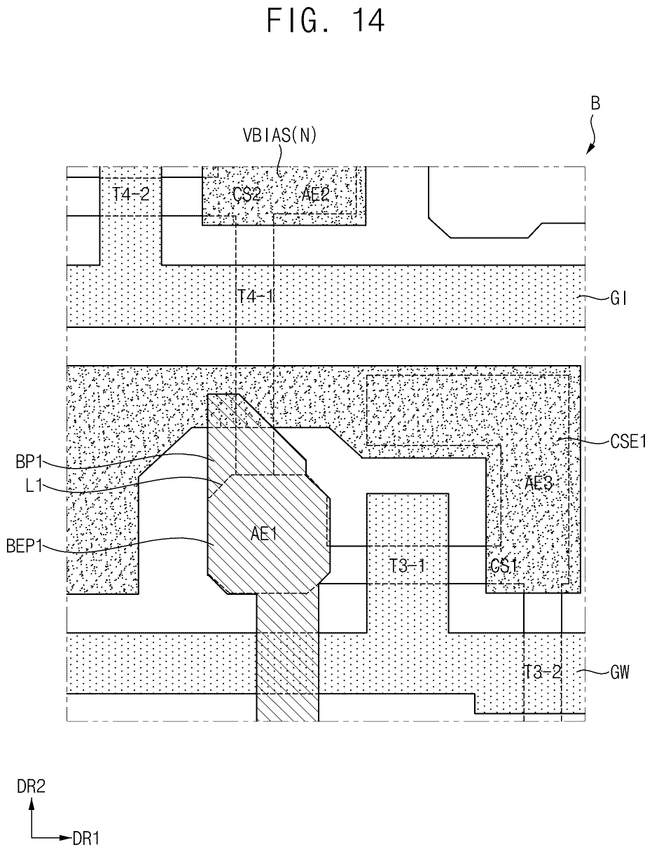

FIG. 13 is an enlarged plan view of an area B in FIG. 12. FIGS. 14, 15, and 16 are layout views illustrating the display device in FIG. 13.

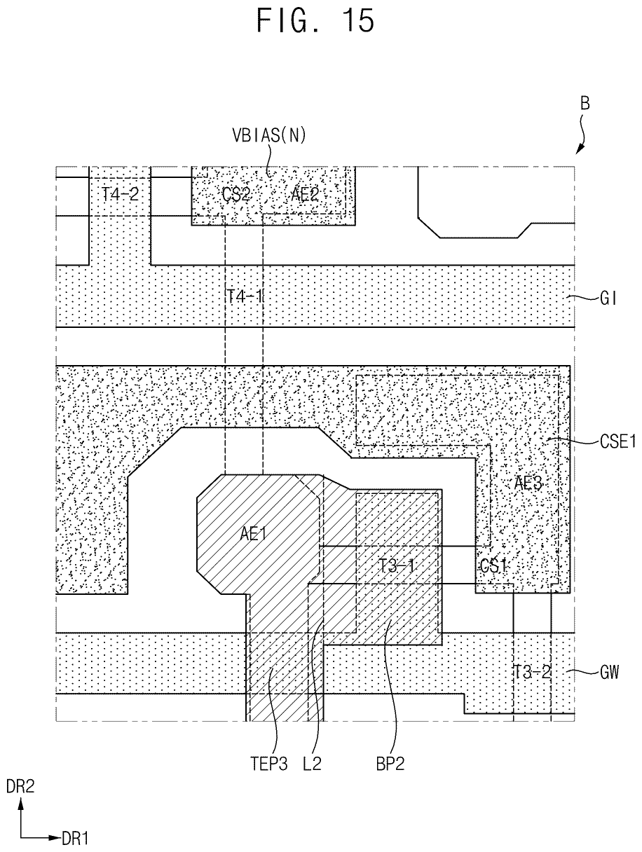

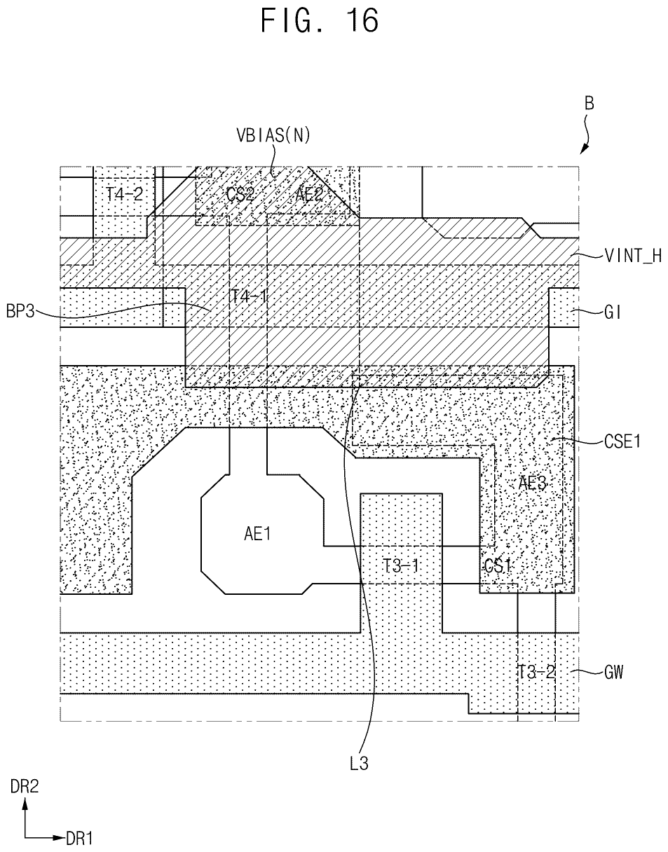

For example, FIG. 14 is a plan view in which only the active pattern ACT, the first gate voltage line GW, the second gate voltage line GI, the first stabilization electrode CSE1, and the first bottom electrode pattern BEP1 in FIG. 13 are illustrated. FIG. 15 is a plan view in which only the active pattern ACT, first gate voltage line GW, second gate voltage line GI, first stabilization electrode CSE1, and third top electrode pattern TEP3 in FIG. 13 are illustrated. FIG. 16 is a plan view in which the active pattern ACT, the first gate voltage line GW, the second gate voltage line GI, the first stabilization electrode CSE1, and the horizontal portion VINT_H of the first initialization voltage line are illustrated.

Referring to FIG. 13, in an embodiment, the first blocking pattern BP1 and the third blocking pattern BP3 may be spaced apart from each other in the second direction DR2. Alternatively, not illustrated in FIG. 13, the first and third blocking patterns BP1 and BP3 may overlap each other in a thickness direction. The first stabilization electrode CSE1 may be disposed between the first blocking pattern BP1 and the third blocking pattern BP3 in the second direction DR2, and overlap each of the first blocking pattern BP1 and the third blocking pattern BP3 in a plan view.

The first blocking pattern BP1, the first stabilization electrode CSE1, and the third blocking pattern BP3 collectively may entirely cover the active pattern forming the third sub-transistor T4-1 except a portion of the second area AE2. The second blocking pattern BP2 may entirely cover the active pattern forming the first sub-transistor T3-1 except a portion of the third area AE3.

Referring to FIG. 14, the first blocking pattern BP1 may be a protruding portion which protrudes from a first line L1 of the first bottom electrode pattern BEP1 in the second direction DR2 toward the third sub-transistor T4-1. The first line L1 may be an imaginary line which circumscribes a portion of the first area AE1 disposed adjacent to the third sub-transistor T4-1. The first blocking pattern BP1 may overlap a portion of the first stabilization electrode CSE1 in a plan view. Alternatively, the first blocking pattern BP1 may not overlap the first stabilization electrode CSE1 in a plan view but may adjoin the first stabilization electrode CSE1 in a plan view.

Referring to FIG. 15, the second blocking pattern BP2 may be a protruding portion which protrudes from a second line L2 of the third top electrode pattern TEP3 in the first direction DR1. The second blocking pattern BP2 may be a portion of the first horizontal power voltage line ELVDD_H. The second line L2 may be an imaginary line which circumscribes a portion of the first area AE1 disposed adjacent to the first sub-transistor T3-1.

Referring to FIG. 16, the third blocking pattern BP3 may be a protruding portion which protrudes from a third line L3 of the horizontal portion VINT_H of the first initialization voltage line in the direction opposite to the first direction DR1. The third line L3 may be an imaginary line which circumscribes the second area AE2 disposed adjacent to the third sub-transistor T4-1.

Hereinafter, effects of the present disclosure according to a comparative example and examples will be described.

According to Example 1, a structure including the third blocking pattern BP3 whose area BP3 is 2.9 μm² was manufactured. According to Example 2, a structure including the second blocking pattern BP2 whose area is 9.7 μm² and the third blocking pattern BP3 whose area is 2.9 μm² was manufactured. According to Example 3, a structure including the first blocking pattern BP1 whose area is 3.4 μm², the second blocking pattern BP2 whose area is 9.7 μm², and the third blocking pattern BP3 whose area is 2.9 μm² was manufactured.

According to the comparative example, a structure which does not include the first blocking pattern BP1, the second blocking pattern BP2, and the third blocking pattern BP3, and which has sum of exposed areas of the active pattern between the first sub-transistor T3-1 and the third sub-transistor T4-1 of 25.7 μm2 was manufactured. The sum of the exposed areas of the structures according to the comparative example and examples is illustrated in Table 1 below.

TABLE 1

| | area of the first | area of the second | area of the | Sum of |
|---|---|---|---|---|
| | blocking pattern | blocking pattern | third blocking | exposed areas |
| | (μm²) | (μm²) | pattern (μm²) | (μm²) |
| Eample1 | 0 | 0 | 2.9 | 22.8 |
| Eample2 | 0 | 9.7 | 2.9 | 13.1 |
| Eample3 | 3.4 | 9.7 | 2.9 | 9.7 |
| Comparative | 0 | 0 | 0 | 25.7 |
| example | | | | |

In Table 2 below, a visibility index indicating the degree of a flicker phenomenon and light blocking characteristics when the display device is exposed to an external light according to the comparative example and example was measured. The higher the visibility index, the more easily the flicker phenomenon generate and the lower the light blocking characteristics. The unit of the visibility index may be a just noticeable difference (JND).

TABLE 2

| | Visibility index (JND) |
|---|---|
| Eample1 | 1.74 |
| Eample2 | 1.44 |
| Eample3 | 1.33 |
| Comparative example | 4.53 |

As a result, Examples 1, 2, and 3, which include a structure including at least one among the first blocking pattern BP1, the second blocking pattern BP2, and the third blocking pattern BP3, had improved light blocking characteristics compared to the comparative example. Specifically, Example 3 which includes all the first blocking pattern BP1, second blocking pattern BP2, and third blocking pattern BP3, had the best light blocking characteristics.

FIG. 17 is a cross-sectional view illustrating a cross-section taken along line I-I′ of FIG. 13.

Referring to FIG. 17, the display device DD may include a substrate SUB, a buffer layer BUF, the active pattern ACT, the first insulating layer IL1, a first gate electrode GE1, a second gate electrode GE2, the second insulating layer IL2, the first stabilization electrode CSE1, the second stabilization electrode CSE2, the third insulating layer IL3, the vertical portion VAINT_V of the second initialization voltage line, the first bottom electrode pattern BEP1, the first vertical power voltage line ELVDD_V, the first via insulating layer VIA1, the third top electrode pattern TEP3, the horizontal portion VINT_H of the first initialization voltage line, a second via insulation layer VIA2, the pixel electrode PXE, a pixel defining layer PDL, a light-emitting layer EML, a common electrode CE, and an encapsulation layer TFE.

The substrate SUB may include a transparent material or an opaque material. The substrate SUB may include a transparent resin substrate. For example, the transparent resin substrate include a polyimide substrate. In this case, the polyimide substrate SUB may include a first organic layer, a first barrier layer, a second organic layer, and the like. Alternatively, the substrate SUB may include a quartz substrate, a synthetic quartz substrate, a calcium fluoride substrate, a non-alkali glass substrate, and the like. These may be used in alone or in combination with each other.

The buffer layer BUF may be disposed on the substrate SUB. The buffer layer BUF may prevent impurities from diffusing from the substrate SUB to the active pattern ACT. The buffer layer BUF may include an inorganic insulating material. The inorganic insulating material may include silicon nitride (SiNx), silicon oxide (SiOx), silicon oxynitride (SiOxNy), and the like. These may be in used alone or in combination with each other.

The active pattern ACT may include a silicon semiconductor material. For example, the silicon semiconductor material may include amorphous silicon, polycrystalline silicon, and the like. Alternatively, the active pattern ACT may include an oxide semiconductor material. For example, the oxide semiconductor material may include indium gallium zinc oxide (IGZO), indium gallium zinc oxide (IGO), indium zinc oxide (IZO), and the like. These may be used in alone or in combination with each other.

The first insulating layer IL1 may be disposed on the buffer layer BUF. The first insulating layer IL1 may cover the active pattern ACT disposed on the buffer layer BUF. For example, the first insulating layer IL1 may have a substantially uniform thickness along the profile of the active pattern ACT. Alternatively, the first insulating layer IL1 may sufficiently cover the active pattern ACT and may have a substantially flat upper surface without creating a step around the active pattern ACT.

The first insulating layer IL1 may include an inorganic insulating material. The inorganic insulating material may include silicon nitride (SiNx), silicon oxide (SiOx), silicon oxynitride (SiOxNy), and the like. These may be used in alone or in combination with each other.

The first gate electrode GE1 and the second gate electrode GE2 may be portions of the first conductive layer (e.g., the first conductive layer CL1 in FIG. 5). The first conductive layer may include a conductive material. For example, the first conductive layer may include silver (Ag), molybdenum (Mo), aluminum (Al), aluminum nitride (AlxNy), tungsten (W), tungsten nitride (WxNy), copper (Cu), indium tin oxide (ITO), indium zinc oxide (IZO), and the like. These may be used alone or in combination with each other.

The first gate electrode GE1 may be a portion where a portion of the first gate voltage line GW of the first conductive layer overlaps the active pattern ACT. For example, the first gate electrode GE1 may overlap the first channel area T3-1c and the third channel area T3-2c of the active pattern ACT. Accordingly, the first gate electrode GE1 and the first channel area T3-1c may together form the first sub-transistor T3-1. In addition, the second gate electrode GE2 and the third channel area T3-2c may together form the second sub-transistor T3-2.

The second gate electrode GE2 may be a portion where a portion of the second gate voltage line GI of the first conductive layer overlaps the active pattern ACT. For example, the second gate electrode GE2 may overlap the second channel area T4-1c and the fourth channel area T4-2c of the active pattern ACT. Accordingly, the second gate electrode GE2 and the second channel area T4-1c may together form the third sub-transistor T4-1. Additionally, the second gate electrode GE2 and the fourth channel area T4-2c may together form the fourth sub-transistor T4-2.

The second insulating layer IL2 may be disposed on the first gate electrode GE1 and the second gate electrode GE2. The second insulating layer IL2 may cover the first conductive layer. The second insulating layer IL2 may have a substantially uniform thickness along the profiles of each of the first gate electrode GE1 and the second gate electrode GE2. Alternatively, the second insulating layer IL2 may sufficiently cover each of the first gate electrode GE1 and the second gate electrode GE2, without creating a step around the first gate electrode GE1 and the second gate electrode GE2.

The second insulating layer IL2 may include an inorganic insulating material. The inorganic insulating material may include silicon nitride (SiNx), silicon oxide (SiOx), silicon oxynitride (SiOxNy), and the like. These may be used in alone or in combination with each other.

The first stabilization electrode CSE1 and the second stabilization electrode CSE2 may be portions of the second conductive layer (e.g., the second conductive layer CL2 in FIG. 7). The second conductive layer may include a conductive material. For example, the second conductive layer may include silver (Ag), molybdenum (Mo), aluminum (Al), aluminum nitride (AlxNy), tungsten (W), tungsten nitride (WxNy), copper (Cu), and indium. It may include tin oxide (indium tin oxide (ITO)), indium zinc oxide (IZO), etc., and they may be used alone or in combination with each other.

The first stabilization electrode CSE1 and the second stabilization electrode CSE2 may be disposed on the second insulating layer IL2. The first stabilization electrode CSE1 may form the first stabilization capacitor CS1 together with the third area AE3 of the active pattern ACT. The second stabilization electrode CSE2 may form a second stabilization capacitor CS2 together with the second area AE2 of the active pattern ACT.

The third insulating layer IL3 may be disposed on the first stabilization electrode CSE1 and the second stabilization electrode CSE2. The third insulating layer IL3 may be disposed on the second conductive layer. The third insulating layer IL3 may cover the second conductive layer. The third insulating layer IL3 may have a substantially uniform thickness along the profiles of each of the first stabilization electrode CSE1 and the second stabilization electrode CSE2. Alternatively, the third insulating layer IL3 may sufficiently cover each of the first stabilization electrode CSE1 and the second stabilization electrode CSE2 without creating a step around the first stabilization electrode CSE1 and the second stabilization electrode CSE2.

The third insulating layer IL3 may include an inorganic insulating material. The inorganic insulating material may include silicon nitride (SiNx), silicon oxide (SiOx), silicon oxynitride (SiOxNy), and the like. These may be used in alone or in combination with each other.

The vertical portion VAINT_V of the second initialization voltage line, the first bottom electrode pattern BEP1, and the first vertical power voltage line ELVDD_V may be formed of the third conductive layer (e.g., the third conductive layer CL3 in FIG. 9). The third conductive layer may be disposed on the third insulating layer IL3.

The third conductive layer may include a conductive material. For example, the third conductive layer may include silver (Ag), molybdenum (Mo), aluminum (Al), aluminum nitride (AlxNy), tungsten (W), tungsten nitride (WxNy), copper (Cu), indium tin oxide (ITO), indium zinc oxide (IZO), and the like. These may be used in alone or in combination with each other. In addition, the third conductive layer may have a single-layer or multi-layer structure containing at least one of the above-mentioned materials.

The first blocking pattern BP1, which is portion of the first bottom electrode pattern BEP1, may overlap a portion of the first stabilization electrode CSE1. However, the first blocking pattern BP1 may not overlap with the second gate electrode GE2 included in the second sub-transistor T4-1.

The first via insulating layer VIA1 may be disposed on the third conductive layer. The first via insulating layer VIA1 may include an organic insulating material such as polyimide (PI).

The third top electrode pattern TEP3 and the horizontal portion VINT_H of the first initialization voltage line may be portions of the fourth conductive layer (e.g., the fourth conductive layer CL4 in FIG. 11). The fourth conductive layer may be disposed on the first via insulating layer VIAL. The first via insulating layer VIA1 may have a substantially flat top surface.

The fourth conductive layer may include a conductive material. For example, the fourth conductive layer may include silver (Ag), molybdenum (Mo), aluminum (Al), aluminum nitride (AlxNy), tungsten (W), tungsten nitride (WxNy), copper (Cu), indium tin oxide (ITO), indium zinc oxide (IZO), and the like. These may be used in alone or in combination with each other. In addition, the fourth conductive layer may have a single-layer or multi-layer structure including at least one of the above-mentioned materials.

The second blocking pattern BP2, which is a portion of the third top electrode pattern TEP3, may overlap the first gate electrode GE1 included in the first sub-transistor T3-1. For example, an end of the second blocking pattern BP2 may extend in the first direction DR1 to completely cover the first channel area T3-1c.

The third blocking pattern BP3, which is portion of the horizontal portion VINT_H of the first initialization voltage line, may overlap the second gate electrode GE2 included in the third sub-transistor T4-1. The third blocking pattern BP3 may overlap all portions of the second gate electrode GE2 in the first direction DR1 in a cross-sectional view. In addition, an end of the third blocking pattern BP3 may overlap a portion of the second gate electrode GE2 constituting the fourth sub-transistor T4-2. However, the present disclosure may not be limited to this.

A second via insulating layer VIA2 may be disposed on the fourth conductive layer. The second via insulating layer VIA2 may include an organic insulating material such as polyimide (PI). The second via insulating layer VIA2 may have a substantially flat top surface.

The pixel electrode PXE may be disposed on the second via insulating layer VIA2. The pixel electrode PXE may include metal, alloy, metal nitride, conductive metal oxide, transparent conductive material, and the like. These may be used in alone or in combination with each other.

The pixel defining layer PDL may be disposed on the pixel electrode PXE. The pixel defining layer PDL may partially cover the pixel electrode PXE. In addition, an opening that exposes at least a portion of the pixel electrode PXE may be defined in the pixel defining layer PDL. For example, the opening of the pixel defining layer PDL may expose a central portion of the pixel electrode PXE, and the pixel defining layer PDL may cover edges of the pixel electrode PXE. The pixel defining layer PDL may include an organic insulating material such as polyimide (PI).

In an embodiment, the pixel defining layer PDL may further include a light blocking material. The light blocking material may include a black dye, a black pigment, a metal (e.g., carbon black, chrome, and the like), and a metal oxide. Accordingly, the pixel defining layer PDL including a light blocking material blocks the external light incident into the first sub-transistor T3-1 and the third sub-transistor T4-1, thereby decreasing the leakage current and the flicker due to the external light. The flicker phenomenon may further decrease, and the low-frequency characteristics of the display device may be further improved.

The light-emitting layer EML may be disposed on the pixel electrode PXE. The light-emitting layer EML may be disposed on the pixel electrode PXE exposed by the opening of the pixel defining layer PDL. The light-emitting layer EML may include organic light emitting materials, quantum dots, and the like.

The common electrode CE may be disposed on the light-emitting layer EML and the pixel defining layer PDL. The common electrode CE may include aluminum (Al), platinum (Pt), silver (Ag), magnesium (Mg), gold (Au), chromium (Cr), tungsten (W), titanium (Ti), and the like. These may be used in alone or in combination with each other.

The light-emitting element LED may include the pixel electrode PXE, the light-emitting layer EML, and the common electrode (CE).

The encapsulation layer TFE may be disposed on the common electrode CE. The encapsulation layer TFE may include at least one inorganic encapsulation layer and at least one organic encapsulation layer. The inorganic encapsulation layer may include silicon nitride (SiNx), silicon oxide (SiOx), silicon oxynitride (SiOxNy), and the like. These may be used alone or in combination with each other. The organic encapsulation layer may include an organic insulating material.

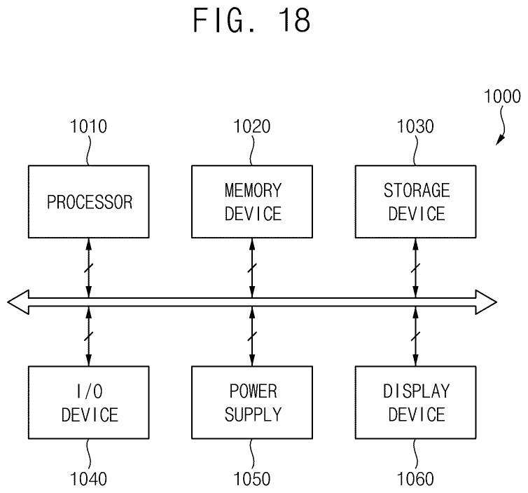

FIG. 18 is a block diagram illustrating an electronic device according to an embodiment.

Referring to FIG. 18, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

The display device according to the embodiments may be applied to an electronic device included in a computer, a notebook, a mobile phone, a smartphone, a smart pad, a PMP, a PDA, an MP3 player, or the like.

Although the display device according to the embodiments has been described with reference to the drawings, the illustrated embodiments are examples, and may be modified and changed by a person having ordinary knowledge in the relevant technical field without departing from the technical spirit described in the following claims.

What is claimed is:

1. A display device comprising:
a substrate;
an active pattern disposed on the substrate and including a first area, a first channel area disposed adjacent to the first area in a first direction, a second area spaced apart from the first area in a second direction intersecting the first direction, and a second channel area disposed between the first area and the second area;
a first conductive layer disposed on the active pattern and including a first gate voltage line overlapping the first channel area and a second gate voltage line overlapping the second channel area;
a second conductive layer disposed on the first conductive layer and including a bias line overlapping the second area and a first stabilization electrode overlapping a portion of the first area;
a first electrode pattern disposed on the second conductive layer and including a first blocking pattern protruding from a portion overlapping the first area toward the second channel area;
a second electrode pattern disposed on the first electrode pattern and including a second blocking pattern protruding from a portion overlapping the first electrode pattern toward the first channel area and overlapping the first channel area; and
a first initialization voltage line disposed on the first electrode pattern, including a third blocking pattern overlapping the second channel area, and extending along the first direction.

2. The display device of claim 1, wherein the first blocking pattern overlaps a portion of the first stabilization electrode.

3. The display device of claim 1, wherein the first blocking pattern adjoins the first stabilization electrode in a plan view.

4. The display device of claim 1, wherein the third blocking pattern overlaps a portion of the first stabilization electrode.

5. The display device of claim 1, wherein the active pattern further includes a third area disposed adjacent to the first channel area in the first direction, a third channel area disposed adjacent to the third area in a direction opposite to the second direction, and a fourth channel area disposed adjacent to the second area in a direction opposite to the first direction.

6. The display device of claim 5, wherein the third blocking pattern overlaps at least a portion of the fourth channel area.

7. The display device of claim 5, wherein a portion of the first gate voltage line overlaps the third channel area, and
a portion of the second gate voltage line overlaps the fourth channel area.

8. The display device of claim 7, wherein the first gate voltage line includes first gate electrodes overlapping the first channel area and the third channel area, respectively, and
wherein the first channel area, the third channel area, and the first gate electrodes form a compensate transistor.

9. The display device of claim 7, wherein the second gate voltage line includes second gate electrodes overlapping the second channel area and the fourth channel area, and
wherein the second channel area, the fourth channel area, and the second gate electrodes form an initialization transistor.

10. The display device of claim 5, wherein the first stabilization electrode overlaps the third area of the active pattern to form a first stabilization capacitor.

11. The display device of claim 1, wherein the bias voltage line overlaps the second area of the active pattern to form a second stabilization capacitor.

12. The display device of claim 1, further comprising:
a second initialization voltage line disposed on a same layer as the first electrode pattern, overlapping each of a portion of the first channel area and a portion of the second blocking pattern, and extending along the second direction; and
a power voltage line disposed on a same layer as the first initialization voltage line and formed integrally with the second electrode pattern.

13. The display device of claim 12, further comprising:
a light-emitting element layer disposed on the first initialization voltage line and the power voltage line and including a pixel electrode, a light-emitting layer disposed on the pixel electrode, and a common electrode disposed on the light-emitting layer; and
a pixel defining layer disposed on the pixel electrode and including a light-blocking material.

14. A display device comprising:
a light-emitting element;
a driving transistor configured to supply a driving current to the light-emitting element;
a compensate transistor including a first sub-transistor and a second sub-transistor, the first sub-transistor including an output terminal electrically connected to a gate electrode of the driving transistor, the second sub-transistor including an output terminal electrically connected to an input terminal of the first sub-transistor and an input terminal electrically connected to an output terminal of the driving transistor;
an initialization transistor including a third sub-transistor and a fourth sub-transistor, the third sub-transistor including an output terminal electrically connected to the gate electrode of the driving transistor, the fourth sub-transistor including an output terminal electrically connected to an input terminal of the third sub-transistor and an input terminal electrically connected to an initialization voltage line;
a first blocking pattern disposed on the gate electrode of the driving transistor and disposed between a portion of an active pattern intersecting with the output terminal of the first sub-transistor and the output terminal of the third sub-transistor and the third sub-transistor;
a second blocking pattern disposed on the first blocking pattern and overlapping at least a portion of the first sub-transistor; and
a third blocking pattern disposed on the first blocking pattern and overlapping the third sub-transistor and at least a portion of the fourth sub-transistor.

15. The display device of claim 14, further comprising:
a first electrode pattern electrically connecting the gate electrode of the driving transistor and each of the output terminal of the first sub-transistor and the output terminal of the third sub-transistor.

16. The display device of claim 15, wherein the first blocking pattern is formed integrally with the first electrode pattern.

17. The display device of claim 15, wherein the second blocking pattern is formed integrally with a second electrode pattern and a power voltage line, the second electrode pattern overlapping a portion of the first blocking pattern, the power voltage line extended from the second electrode pattern, and
wherein the third blocking pattern is formed integrally with the initialization voltage line disposed on a same layer as the power voltage line.

18. The display device of claim 14, further comprising:
a first stabilization capacitor disposed on each of the first sub-transistor and the second sub-transistor and located between the first sub-transistor and the second sub-transistor; and
a second stabilization capacitor disposed on each of the third sub-transistor and the fourth sub-transistor and located between the third sub-transistor and the fourth sub-transistor.

19. The display device of claim 18, wherein the first stabilization capacitor includes a first stabilization electrode overlapping a portion of the active pattern disposed between the input terminal of the first sub-transistor and the output terminal of the second sub-transistor, and
wherein the second stabilization capacitor includes a second stabilization electrode overlapping a portion of the active pattern disposed between the input terminal of the third sub-transistor and the output terminal of the fourth sub-transistor.

20. The display device of claim 19, wherein each of the first blocking pattern and the third blocking pattern overlaps a portion of the first stabilization electrode.

21. An electronic device comprising:
a display device; and
a power supply configured to provide power to the display device,
wherein the display device comprises:
a substrate;
an active pattern disposed on the substrate and including a first area, a first channel area disposed adjacent to the first area in a first direction, a second area spaced apart from the first area in a second direction intersecting the first direction, and a second channel area disposed between the first area and the second area;
a first conductive layer disposed on the active pattern and including a first gate voltage line overlapping the first channel area and a second gate voltage line overlapping the second channel area;
a second conductive layer disposed on the first conductive layer and including a bias line overlapping the second area and a first stabilization electrode overlapping a portion of the first area;
a first electrode pattern disposed on the second conductive layer and including a first blocking pattern protruding from a portion overlapping the first area toward the second channel area;
a second electrode pattern disposed on the first electrode pattern and including a second blocking pattern protruding from a portion overlapping the first electrode pattern toward the first channel area and overlapping the first channel area; and
a first initialization voltage line disposed on the first electrode pattern, including a third blocking pattern overlapping the second channel area, and extending along the first direction.
